(19) United States
(12) Patent Application Publication
(10) Pub. No.: US 2026/0324018 A1
(43) Pub. Date: Oct. 15, 2026

(54) SEMICONDUCTOR STRUCTURE WITH DUMMY CHANNEL FEATURE AND METHOD FOR MANUFACTURING THE SAME

(71) Applicant: TAIWAN SEMICONDUCTOR MANUFACTURING COMPANY, LTD., Hsinchu (TW)

(72) Inventors: Chih-Hao WANG, Hsinchu (TW); Chen-Han LU, Hsinchu (TW); Yu-Xuan HUANG, Hsinchu (TW); Kuo-Cheng CHIANG, Hsinchu (TW); Cheng-Chi CHUANG, Hsinchu (TW)

(73) Assignee: TAIWAN SEMICONDUCTOR MANUFACTURING COMPANY, LTD., Hsinchu (TW)

(21) Appl. No.: 19/175,379

(22) Filed: Apr. 10, 2025

(51) Int. Cl. H10D 62/10; H01L 21/683; H01L 21/762; H10D 30/01; H10D 30/62; H10D 30/67; H10D 64/66; H10D 84/01; H10D 84/83

(52) U.S. Cl. CPC H10D 62/124; H10D 30/024; H10D 30/62; H10D 30/6735; H10D 30/6757; H10D 64/66; H10D 84/0158; H10D 84/834; H10P 72/74; H10W 10/014; H10W 10/17

(57) ABSTRACT

A semiconductor structure includes: an active channel feature and a dummy channel feature disposed beneath the active channel feature; two source/drain features; a gate structure; and a dielectric feature. The two source/drain features are disposed at two opposite sides of a combination of the active channel feature and the dummy channel feature in a first direction, and are interconnected by the active channel feature. The gate structure is formed to surround the active channel feature and formed over the dummy channel feature. The gate structure extends lengthwise along a second direction different from the first direction. The gate structure includes a Ti-based gate electrode and a gate dielectric. The dielectric feature has an upper surface connected to a lower surface of the dummy channel feature opposite to the active channel feature.

### BACKGROUND

Semiconductor technology is continuously evolving with devices that use varying numbers of channels. The performance characteristics of these devices—such as carrier mobility, switching speed, and power consumption—depends on the number of channels. Devices with more channels can enhance drive current and switching characteristics, while those with fewer channels tend to offer lower power consumption and higher efficiency. Current research focuses on optimizing channel structures, material selection, and fabrication techniques to develop high-performance, low-power devices, particularly for applications involving quantum effects and high-frequency operations. These advancements are driving semiconductor devices toward improved performance and miniaturization.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 28 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

Source/drain feature(s) may refer to a source or a drain, individually or collectively dependent upon the context.

The gate-all-around (GAA) transistor with sheet structures offers enhanced short-channel control with an improved effective channel width (W_{eff}). In particular, a hybrid channel structure (e.g., a structure including devices with different numbers of channels) is designed for low energy consumption, which is beneficial for achieving a better PPA (power, performance, and area) or more specifically, for achieving an improved performance per watt.

The present disclosure is directed to provide a semiconductor structure. The semiconductor structure includes an active channel feature, a dummy channel feature, two source/drain features, a gate structure, and a dielectric feature. The dummy channel feature is disposed beneath the active channel feature. The two source/drain features are disposed at two opposite sides of a combination of the active channel feature and the dummy channel feature in a first direction, and are interconnected by the active channel feature. The gate structure is formed to surround the channel feature and is formed over the dummy channel feature. The gate structure extends lengthwise along a second direction different from the first direction. The dielectric feature is connected to a lower surface of the dummy channel feature opposite to the active channel feature. Such configuration permits the semiconductor structure to have a relatively low parasitic capacitance and superior electrical properties, thereby saving power and energy. The semiconductor structure of the present disclosure may be formed by firstly, forming a patterned structure which includes an active region, a stack portion and a dummy structure. The active region is disposed between two isolation features. The stack portion is disposed on the active region, and includes first semiconductor features and second semiconductor features that are alternately stacked. The dummy structure is formed over the stack portion and the two isolation features. Secondly, a first replacement process is performed to replace the second semiconductor features with dielectric features, respectively. Thereafter, two blocking layers are formed, such that two ends of a lower one of the dielectric features and two ends of a lower one of the first semiconductor features are respectively covered by the two blocking layers, and such that two ends of an upper one of the dielectric features and two ends of an upper one of the first semiconductor features are exposed from the two blocking layers. Next, a second replacement process is performed to replace the upper one of the dielectric features with a sacrificial interposer, followed by forming the two source/drain features respectively on the two blocking layers. Then, after the sacrificial interposer and the dummy structure are removed, the gate structure is formed to obtain the semiconductor structure. That is, the upper one of the dielectric features is to be removed and will not be present in the resultant semiconductor structure. The upper one of the first semiconductor features serves as an active channel feature, and the lower one of the first semiconductor features serves as a dummy channel feature. The lower one of the dielectric features remains in the resultant semiconductor structure. The method for manufacturing the semiconductor structure may be used for semiconductor devices with different numbers of channels (e.g., a combination of a 2-channel GAA transistor, and a 3-channel GAA transistor or other suitable devices).

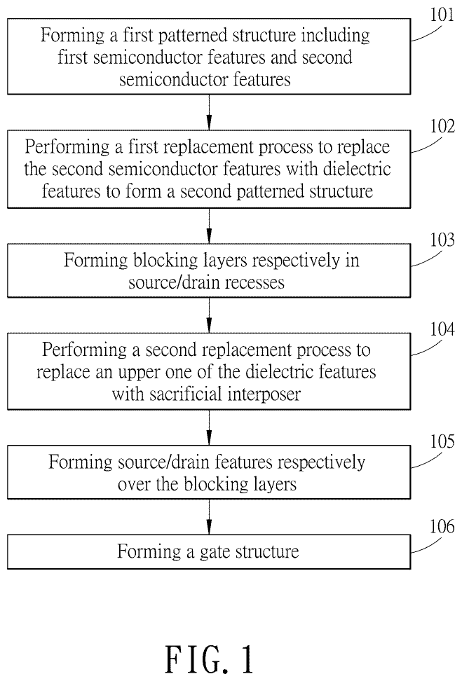

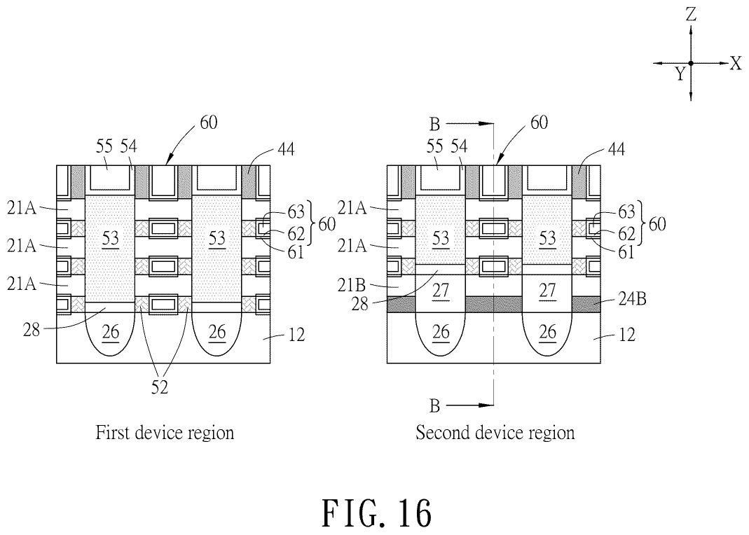

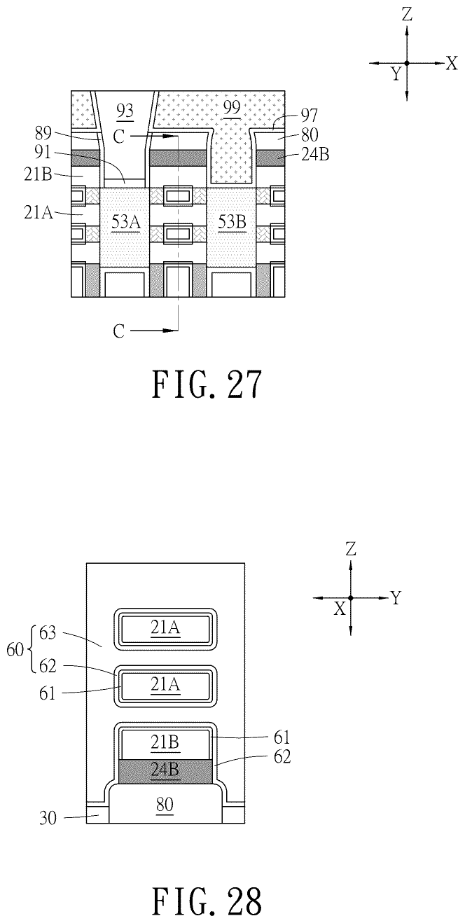

FIG. 1 is a flow diagram illustrating a method for manufacturing the semiconductor structure (for example, the semiconductor structure shown in FIG. 16 or 27) in accordance with some embodiments. FIGS. 2 to 28 illustrate schematic views of intermediate stages of the method in accordance with some embodiments, and the steps illustrated in FIGS. 2 to 28 are also illustrated schematically in the flow diagram shown in FIG. 1. It should be note that some repeating structures are omitted in FIGS. 2 to 28 for the sake of brevity, that additional steps can be provided before, after or during the method, and that some of the steps described herein may be replaced by other steps or be eliminated.

Referring to FIG. 2, a material stack 2 is formed on a starting substrate 1.

The starting substrate 1 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The starting substrate 1 may be formed with an n-type well (not shown) having an n-type conductivity and/or a p-type well (not shown) having a p-type conductivity. Each of the n-type well and the p-type well may be formed by introducing an n-type impurity or a p-type impurity into the starting substrate 1 by an implantation processes. In some embodiments, the n-type impurity may include phosphorous (P, ³¹P), arsenic (As), antimony (Sb), or combinations thereof. In some embodiments, the p-type impurities may include boron or a boron compound (for example, B, ¹¹B, BF₂), aluminum (Al), indium (In), gallium (Ga), or combinations thereof. In some embodiments, the starting substrate 1 may be a bulk silicon substrate, a silicon-on-insulator (SOI) substrate, or a germanium-on-insulator (GOI) substrate. In some embodiments, the starting substrate 1 may be made of silicon. Other suitable materials for forming the starting substrate 1 are within the contemplated scope of the present disclosure.

The material stack 2 includes first material layers 210 and second material layers 220 that are alternatively stacked on each other over the starting substrate 1 and that may be formed using any suitable deposition process, such as physical vapor deposition (PVD), chemical vapor deposition (CVD), atomic layer deposition (ALD), other suitable processes, or combinations thereof, but are not limited thereto. Any deposition process mentioned in the following description, unless otherwise stated or defined in this disclosure, may be performed in a way similar to the above-mentioned ones. In some embodiments, the first material layers 210 are made of a first semiconductor material, and the second material layers 220 are made of a second semiconductor material different from the first semiconductor material. Possible materials for the first and second semiconductor materials are similar to those for the starting substrate 1, and thus details thereof are omitted for the sake of brevity. In some embodiments, the material stack 2 includes three first material layers 210, and three second material layers 220. In some other embodiments, a number of the first material layers 210 or the second material layers 220 may be greater than three or smaller than three. In certain embodiments, the first material layers 210 include or are made of silicon, while the second material layers 220 include or be made of silicon germanium. Other suitable processes, materials, numbers and/or dimensions for each of the first and second material layers 210, 220 are within the contemplated scope of the present disclosure.

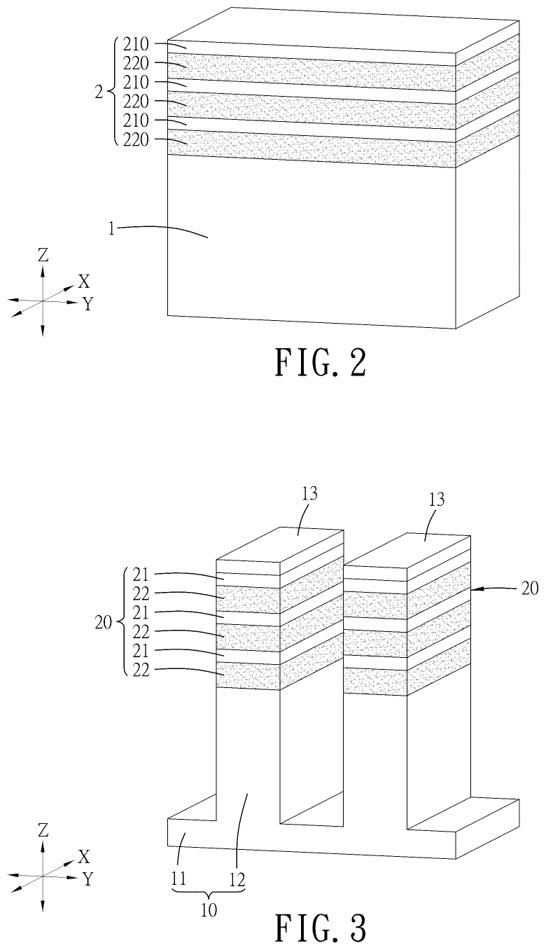

Referring to FIG. 3, a patterning process is performed to pattern the starting substrate 1 (see FIG. 2) into a patterned substrate 10 which includes a base 11 and fins 12 (which may referred to as protrusions on the base 11), and to pattern the material stack 2 (see FIG. 2) into fin stacks 20 which are respectively disposed on the fins 12.

The patterning process may include a photolithography process followed by an etching process. The photolithography process may include: forming a photoresist layer over a structure to be patterned by, e.g., spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, any patterning process mentioned, unless otherwise stated or defined in this disclosure, may be performed in a way similar to the above-mentioned ones. In some embodiments, before the patterning process, a masking layer (not shown, may be made of silicon oxide, silicon nitride, other suitable materials, or combinations thereof) is formed on the material stack 2 using a suitable deposition process; and in the etching process, the masking layer is patterned by the patterned photoresist layer into masking regions 13, and then the starting substrate 1 and the material stack 2 are patterned using the masking regions 13 as an etching mask.

The fins 12 are disposed on the base 11, are each elongated in an X direction, and are spaced apart from each other in a Y direction transverse to (e.g., perpendicular to) the X direction. The fins 12 may be referred to as active regions. The fin stacks 20 are respectively disposed on the fins 12 opposite to the base 11 in the Z direction transverse to (e.g., perpendicular to) the X direction and the Y direction, and thus are spaced apart from each other in the Y direction. The first material layers 210 (see FIG. 2) are patterned to form first semiconductor films 21 of the fin stacks 20; and the second material layers 220 (see FIG. 2) are patterned to form second semiconductor films 22 of the fin stacks 20. Each of the first semiconductor films 21 may have a width (measured in the Y direction) ranging from about 15 nm to about 50 nm, but are not limited thereto. Other suitable processes and/or dimensions for the first semiconductor films 21 and the second semiconductor films 22 are within the contemplated scope of the present disclosure.

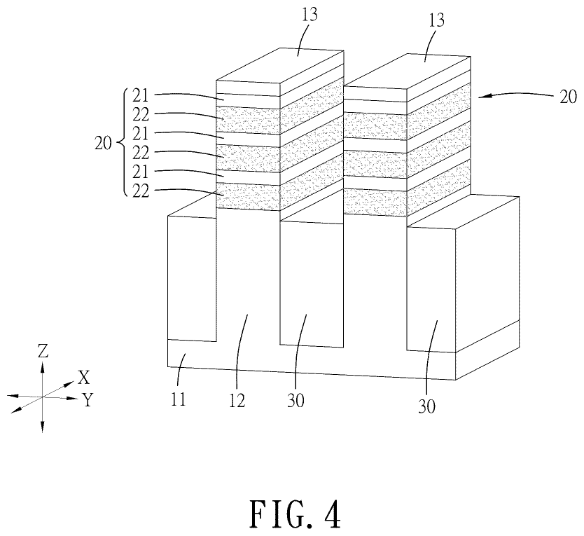

Referring to FIG. 4, isolation features 30 are formed. Each of the isolation features 30 is formed on the base 11 between two adjacent ones of the fins 12, and is elongated in the X direction. In some embodiments, the isolation features 30 are each a shallow isolation features (STI), a deep trench isolation (DTI), or other suitable structures. The isolation features 30 may be formed by: depositing an isolation material for forming the isolation features 30 using any suitable deposition process over the structure shown in FIG. 3 such that the isolation material fills spaces among the fin stacks 20; performing a planarization process (e.g., chemical mechanical polishing (CMP)) to obtain a planarized surface, through which the masking regions 13 remaining respectively on the fin stacks 20 are exposed; and etching back the isolation material using any suitable etching process, such as dry etching, wet etching, anisotropic etching, or combinations thereof. In the following description, any etching process mentioned, unless otherwise stated or defined in this disclosure, may be performed in a way similar to the above-mentioned ones. In some embodiments, after forming the isolation features 30, the masking regions 13 are removed. In some embodiments, upper surfaces of the isolation features 30 may be at a level lower than a level of upper surfaces of the fins 12. In some embodiments, the isolation features 30 include or are made of a dielectric material, such as an oxide-based material (e.g., silicon oxide, silicon oxynitride, silicon oxide formed from tetraethoxysilane (TEOS), or other suitable materials), silicon nitride, other low-k dielectric materials, or combinations thereof. Other suitable processes, materials and/or configurations of the isolation features 30 are within the contemplated scope of the present disclosure.

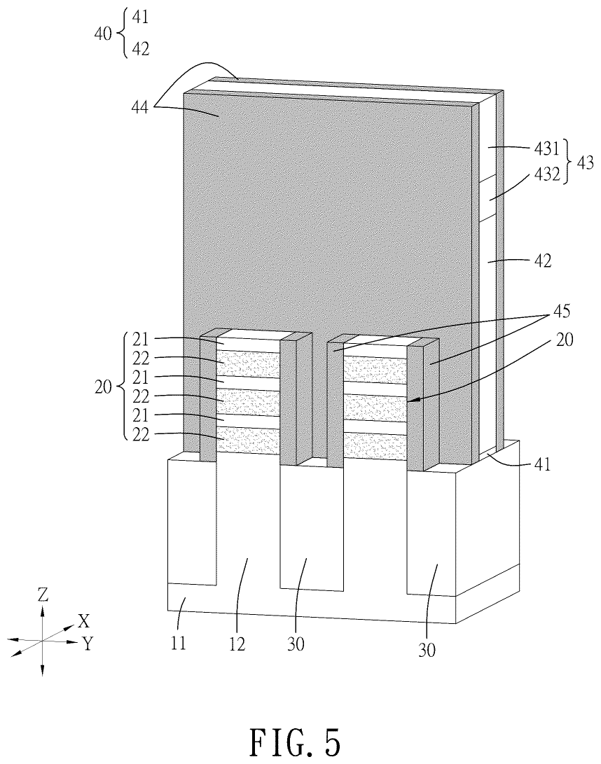

Referring to FIG. 5, a dummy structure 40 and a pair of gate spacers 44 are formed. In some embodiments, the dummy structure 40 is elongated in the Y direction and includes a dummy dielectric 41 and a dummy gate 42. In some embodiments, a mask 43 is formed over the dummy gate 42. The gate spacers 44 sandwich the dummy structure 40 and the mask 43. Each of the fin stacks 20 has a first stack portion which is covered by the dummy structure 40 and the gate spacers 44, and second stack portions which are opposite to each other in the X direction to sandwich the first stack portion. In some embodiments, each of the second stack portions is sandwiched by a corresponding pair of fin sidewalls 45 in the Y direction. The gate spacers 44 extend over the isolation features 30.

In some embodiments, the dummy structure 40 is formed by: depositing first and second dummy layers (not shown) respectively for forming the dummy dielectric 41 and the dummy gate 42 using any suitable deposition process; performing a planarization process (e.g., CMP) to obtain a planar upper surface of the second dummy layer (i.e., a planarized second dummy layer); forming a mask layer (not shown) for forming the mask 43 on the planarized second dummy layer using any suitable deposition process; and patterning the first dummy layer, the planarized second dummy layer and the mask layer to partially expose the fin stacks 20 and the isolation features 30 using any suitable patterning process and/or etching process. Thereafter, a spacer material layer (not shown, for forming the gate spacers 44) is formed over the dummy structure 40, the fin stacks 20 and the isolation features 30 using any suitable deposition process; and patterning the spacer material layer by any suitable patterning process and/or etching process, so as to obtain the gate spacers 44. In some embodiments, the fin sidewalls 45 are formed during formation of the gate spacers 44. Other suitable processes for forming the dummy structure 40, the gate spacers 44 and the fin sidewalls 45 are within the contemplated scope of the present disclosure.

In some embodiments, the dummy dielectric 41 includes or is made of silicon oxide, silicon nitride, silicon oxynitride, high dielectric constant (k) materials, or combinations thereof. The dummy gate 42 includes or is made of polycrystalline silicon, single crystalline silicon, amorphous silicon, or combinations thereof. The mask 43 may be a single layer structure, or a multi-layered structure. The mask 43 includes or is made of a dielectric material, such as silicon nitride, silicon oxide, silicon oxynitride, or combinations thereof. In some embodiments, the mask 43 shown in FIG. 5 is a bi-layer structure including a first mask layer 431 (e.g., a nitride-based dielectric layer) and a second mask layer 432 (e.g., an oxide-based dielectric layer). The gate spacers 44 and the fin sidewall layers 45 include or are made of a same material or different materials. For instance, the gate spacers 44 and the fin sidewall layers 45 include or are made of silicon oxide, silicon nitride, carbon-doped silicon oxide (which may be referred to as silicon oxycarbide), nitride-doped silicon oxide (which may be referred to as silicon oxynitride), silicon oxycarbon nitride, silicon carbon nitride, a porous oxide material, other suitable low dielectric constant (low-k) materials, or combinations thereof. Other suitable materials for each of the dummy dielectric 41, the dummy gate 42, the mask 43, the gate spacers 44 and the fin sidewalls 45 are within the contemplated scope of the present disclosure.

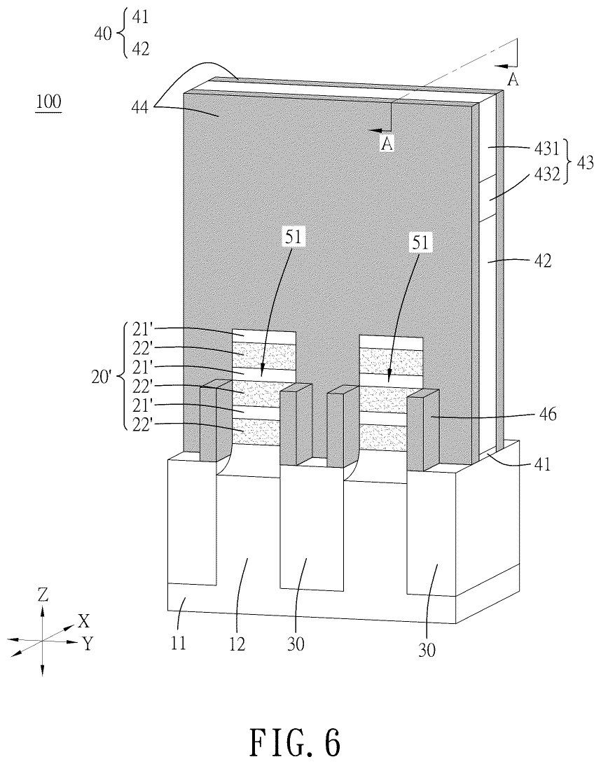

Referring to FIG. 6, the fin stacks 20 (see FIG. 5) are patterned into stack portions 20′ so as to form source/drain recesses 51. In addition, the fin sidewalls 45 (see FIG. 5) are each patterned into fin sidewall portions 46.

In patterning the fin stacks 20, the second stack portions of the fin stacks 20 (see FIG. 5) are removed, and the first stack portions of the fin stacks 20 remain to serve as the stack portions 20′. The first semiconductor films 21 (see FIG. 5) are formed into first semiconductor features 21′, and the second semiconductor films 22 are formed into second semiconductor features 22′. In some embodiments, upper portions of the fins 12 are also patterned. Any suitable patterning process and/or etching process may be employed, while the mask 43 is provided to protect the dummy dielectric 41 and the dummy gate 42. Other suitable processes for forming the source/drain recesses 51 are within the contemplated scope of the present disclosure.

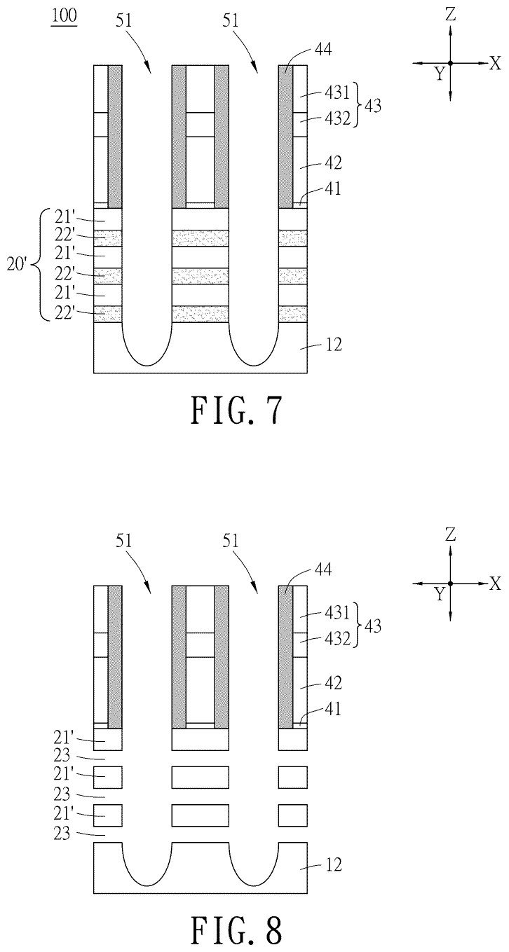

FIG. 7 is a schematic cross-sectional view (X-cut) taken along the line A-A shown in FIG. 6 in accordance with some embodiments. In FIG. 7, another repeating structure (including two additional masks 43, two additional dummy structures 40 and two additional stack portions 20′) is further shown, while the base 11 shown in FIG. 6 is not illustrated in FIG. 7. As shown in FIG. 7, two opposite ends of each of the stack portions 20′ in the X direction are each exposed in a corresponding one of the source/drain recesses 51. The structures shown in FIGS. 6 and 7 may be referred to as a first patterned structure 100. Step 101 in the flow diagram shown in FIG. 1 is exemplified by the structures shown in FIGS. 2 to 7.

Referring to FIG. 8, the second semiconductor features 22′ (see FIG. 7) are removed through the source/drain recesses 51 by using any suitable etching process (e.g., wet etching process, dry etching process, or combinations thereof) or other suitable processes, while the first semiconductor features 21′ remain intact. After removing the second semiconductor features 22′, a plurality of gaps 23 are formed between the first semiconductor features 21′.

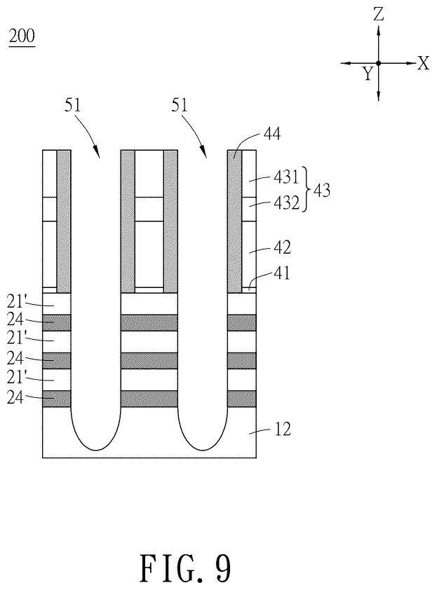

Referring to FIG. 9, dielectric features 24 are formed in the gaps 23 (see FIG. 8), respectively. In some embodiments, the dielectric features 24 are formed by: depositing a dielectric material (not shown, for forming the dielectric features 24) over the structure shown in FIG. 8 to fill the gaps 23 by using any suitable deposition process (e.g., CVD, ALD, or combinations thereof), or other suitable processes; and removing an excess amount of the dielectric material to form the dielectric features 24 by using any suitable etching process (e.g., wet etching process, reactive ion etching process, plasma etching process, or combinations thereof), any suitable trimming process, and/or other suitable process.

In some embodiments, the dielectric features 24 include or are made of silicon oxide, aluminum oxide, hafnium oxide, titanium oxide, zirconium oxide, silicon nitride, silicon carbide, silicon oxynitride, silicon oxycarbide, silicon oxycarbonitride, other suitable materials, or combinations thereof. The structure shown in FIG. 9 may be also referred to a second patterned structure 200. A first replacement process of step 102 in the flow diagram shown in FIG. 1 for replacing the second semiconductor features 22′ with the dielectric features 24 is exemplified by the structures shown in FIGS. 7 to 9. After the first replacement process, the first semiconductor features 21′ and the dielectric features 24 are alternatively stacked.

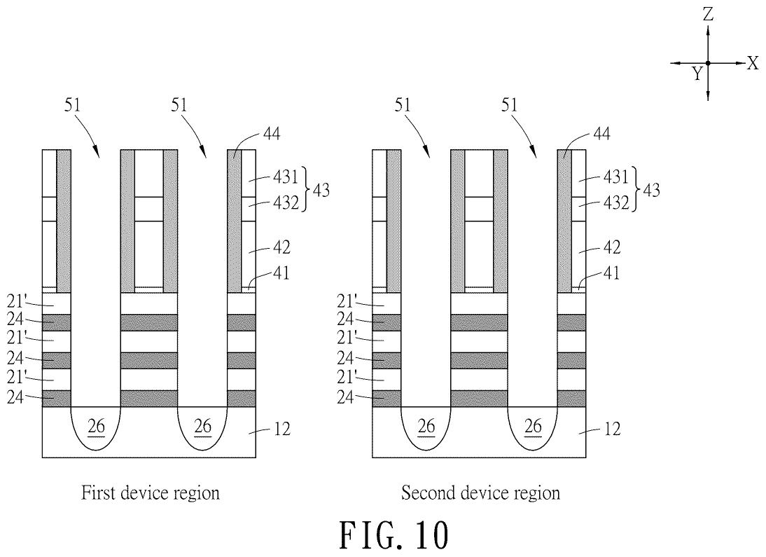

Referring to FIG. 10, bottom epitaxial layers 26 are formed in the source/drain recesses 51, respectively. The bottom epitaxial layers 26 are formed by depositing an epitaxial material in the source/drain recesses 51 by using any suitable deposition process (e.g., atmosphere pressure CVD (APCVD), low pressure CVD (LPCVD), plasma enhanced CVD (PECVD), ACD, epitaxial growing process (such as molecular-beam epitaxy (MBE), selective area epitaxy (SAE), etc.), or combinations thereof), or other suitable processes. In some embodiments, during forming the bottom epitaxial layers 26, any suitable etching gas may also be introduced for removing the epitaxial material formed on sidewalls of the source/drain recesses (e.g., the epitaxial material formed on two ends of the first semiconductor features 21′) so as to permit each of the bottom epitaxial layers 26 to grow in a bottom-up manner. In some embodiments, an upper surface of each of the bottom epitaxial layers 26 is at a level not higher than a lower surface of a bottommost one of the first semiconductor features 21′. In some embodiments, the upper surface of each of the bottom epitaxial layers 26 may be substantially flush with an upper surface of a corresponding one of the fins 12.

In some embodiments, the bottom epitaxial layers 26 include or are made of an elemental semiconductor material (e.g., crystalline silicon, diamond, germanium, or combinations thereof); or a compound semiconductor material (e.g., silicon carbide, gallium arsenide, indium arsenide, indium phosphide, or combinations thereof); or an alloy semiconductor material (e.g., silicon germanium, silicon germanium carbide, gallium arsenide phosphide, gallium indium phosphide, or combinations thereof); or other suitable materials. In some embodiments, the bottom epitaxial layers 26 are made of an epitaxial material having an intrinsic conductivity type.

In some embodiments, referring to FIG. 10, in forming the bottom epitaxial layers 26, the bottom epitaxial layers 26 are formed in each of a first device region and a second device region.

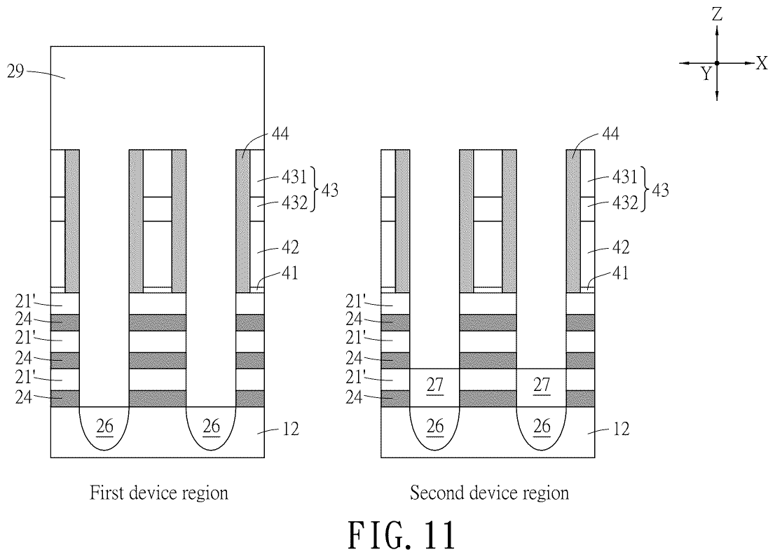

Referring to FIG. 11, a patterned mask 29 is formed to cover the first device region, while the second device region is exposed from the patterned mask 29. The patterned mask 29 may be formed by using a suitable photolithography process or other suitable processes. Then, blocking layers 27 are respectively formed over the bottom epitaxial layers 26 at the second device region. At the second device region, two ends of a lower one of the dielectric features 24 and two ends of an lower one of the first semiconductor features 21′ are covered by two corresponding ones of the blocking layers 27, and two ends of an upper one of the dielectric features 24 and two ends of an upper one of the first semiconductor features 21′ are exposed from the two corresponding blocking layers 27. In some embodiments, at the second device region, upper surfaces of the blocking layers 27 are at a level not lower than a level of an upper surface of the lower one of the dielectric features 24. In some embodiments, at the second device region, the level of the upper surfaces of the blocking layers 27 is not lower than a level of an upper surface of the lower one of the first semiconductor features 21′. In some embodiments, the upper surfaces of the blocking layers 27 and the upper surface of the lower one of the first semiconductor features 21′ are substantially coplanar.

Since possible materials and processes for forming the blocking layers 27 are similar to those for forming the bottom epitaxial layers 26, the details thereof are omitted for the sake of brevity. The bottom epitaxial layers 26 and the blocking layers 27 may be the same or different in material. In some embodiments, the blocking layers 27 are made of an epitaxial material having an intrinsic conductivity type. In some embodiments, the blocking layers 27 and the second semiconductor features 22′ (see FIG. 7) are made of different materials. In some other embodiments, the blocking layers 27 and the second semiconductor features 22′ are made of the same material. Step 103 in the flow diagram shown in FIG. 1 is exemplified by a structure shown in FIG. 11.

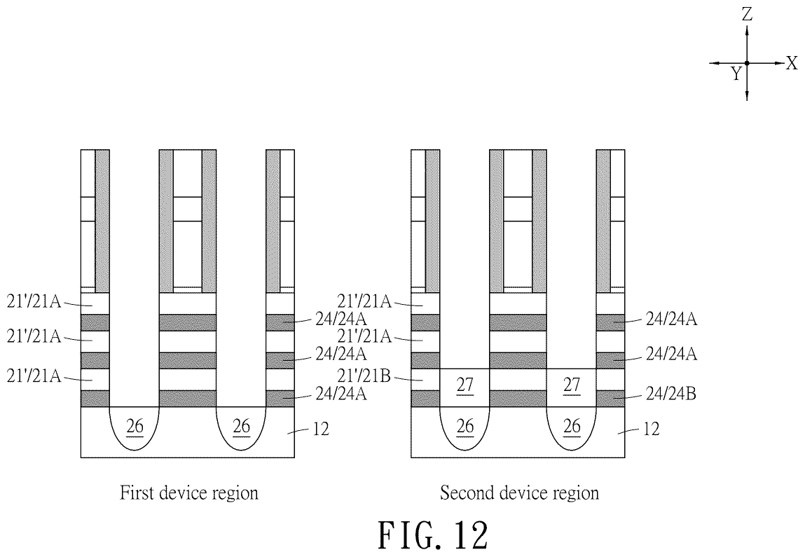

Referring to FIG. 12, the patterned mask 29 (see FIG. 11) is removed using any suitable process (e.g., ashing or etching processes). After removing the patterned mask 29, in the first device region, all of the dielectric features 24 and all of the first semiconductor features 21′ are accessible through the source/drain recesses 51. In the second device region, some of the dielectric features 24 (each of which serves the upper one of the dielectric features) and some of the first semiconductor features 21′ (each of which serves the upper one of the first semiconductor features) are accessible through the source/drain recesses 51. In other words, in the second device region, some other ones of the dielectric features 24 (each of which serves the lower one of the dielectric features) and some other ones of the first semiconductor features 21′ (each of which serves the lower one of the first semiconductor features) are shielded by the blocking layers 27 and are not accessible. In FIG. 12, the accessible dielectric features 24 are also denoted by 24A, and the non-accessible dielectric features 24 are also denoted by 24B. In addition, the accessible first semiconductor features 21′ are also referred to as active channel features or channels 21A, and the non-accessible first semiconductor features 21′ are also referred to as dummy channel features or dummy channels 21B. It is noted that the number of the accessible dielectric features 24A and the number of the channels 21A in the second device region are determined by a height of the blocking layers 27 measured along the Z direction. Therefore, the numbers of the elements 24A and 21A may be varied based on the design (e.g., the height of the element 27 and/or the numbers of the elements 210, 220 shown in FIG. 2) and should not be limited to those illustrated in FIG. 12.

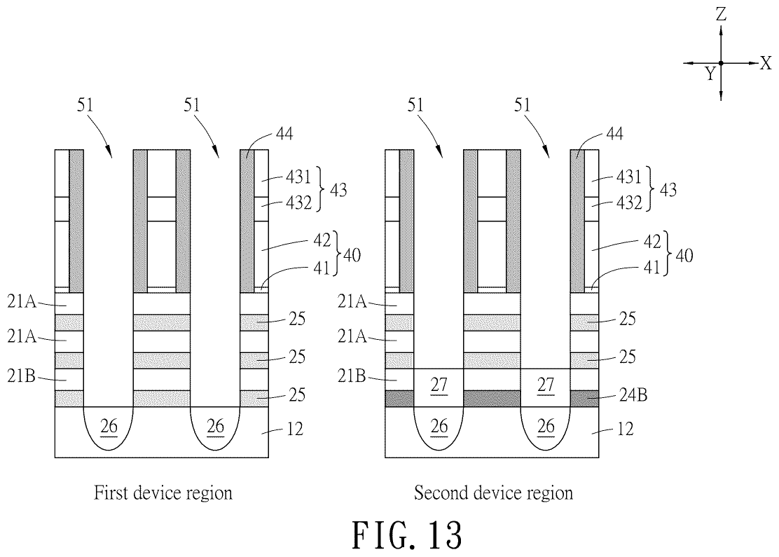

Referring to FIG. 13, a second replacement process is performed to replace the dielectric features 24A at the first and second device regions (see FIG. 12) with sacrificial interposers 25. The dielectric features 24B at the second device region are shaded by the blocking layers 27, and thus remains intact.

In some embodiments, in the second replacement process, all of the dielectric features 24A in the first and second device regions (see FIG. 12) are removed to allow some of the gaps 23 (see FIG. 8), which are originally occupied by the dielectric features 24A, to reappear. The removal of the dielectric features 24A are performed by using any suitable etching process (e.g., wet etching process, dry etching process, or combinations thereof), or other suitable processes. Thereafter, the sacrificial interposers 25 are formed in the reappeared gaps 23 by: depositing a sacrificial interposer material by using any suitable deposition process (e.g., APCVD, LPCVD, PECVD, ALD, or combinations thereof), or other suitable processes to fill the reappeared gaps 23; and removing an excess amount of the sacrificial interposer material by using any suitable etching process (e.g., wet etching process, dry etching process, or combinations thereof), any suitable trimming process, or other suitable process. Step 104 in the flow diagram shown in FIG. 1 is exemplified by structures shown in FIGS. 12 to 13.

In some embodiments, the sacrificial interposers 25 include or are made of a dielectric material (e.g., silicon oxide, aluminum oxide, hafnium oxide, titanium oxide, zirconium oxide, silicon nitride, silicon carbide, silicon oxynitride, silicon oxycarbide, silicon oxycarbonitride, or combinations thereof), or other suitable materials. The sacrificial interposer 25 and the dielectric features 24 are made of different materials.

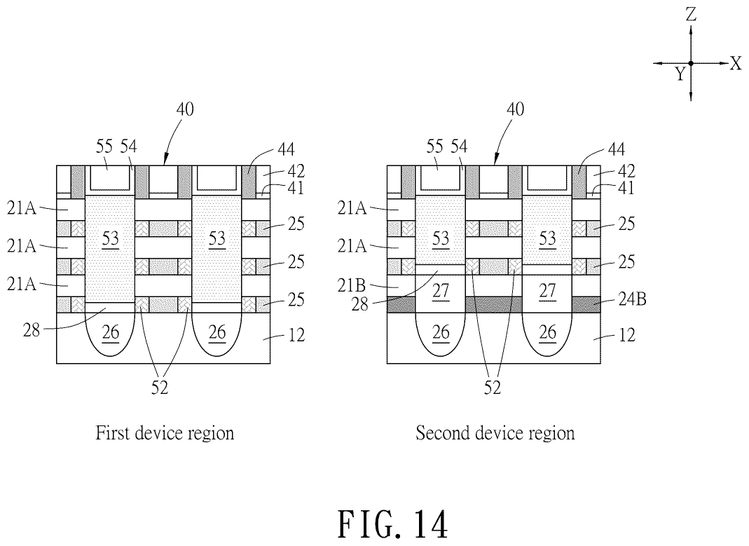

Referring to FIG. 14, at each of the first and second device regions, source/drain features 53 are formed in the source/drain recesses 51, respectively. To be specific, at the first device region, the source/drain features 53 are respectively formed over the bottom epitaxial layers 26, and at the second device region, the source/drain features 53 are respectively formed over the blocking layers 27. The source/drain features 53 include or are made of single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. The source/drain features 53 may each be doped with n-type dopant(s) or p-type dopant(s). Examples for the n-type dopants and the p-type dopants are respectively similar to the n-type impurities and p-type impurities described above, and thus details thereof are omitted for the sake of brevity. In some embodiments, an epitaxy growth process (such as molecular-beam epitaxy (MBE), selective area epitaxy (SAE), etc.) or other suitable deposition techniques may be adopted for forming the source/drain features 53. In some embodiments, the source/drain features 53 may include single epitaxial layer or multiple epitaxy layers (not shown) having different materials and/or different dopant concentrations. In some embodiments, each of the source/drain features 53 includes at least two epitaxy layers (not shown) containing two semiconductor materials that are substantially the same but with different dopant concentrations. In some embodiments, the source/drain features 53 are made of an epitaxial material having one of an n-type conductivity and a p-type conductivity, which is different from that of the blocking layers 27 and/or that of the bottom epitaxial layers 26. Step 105 in the flow diagram shown in FIG. 1 is exemplified by a structure shown in FIG. 14.

In some embodiments, prior to forming the source/drain features 53, inner spacers 52 and bottom isolation features 28 are formed in advance. In some embodiments, the bottom isolation features 28 are formed after forming the inner spacers 52. In some other embodiments, the formation of the inner spacers 52 may be omitted. In certain embodiments, the formation of the bottom isolation features 28 may be omitted.

In some embodiments, the inner spacers 52 are formed by: removing end regions of each of the sacrificial interposers 25 (see FIG. 13) that are opposite to each other in the X direction using any suitable etching process to form recesses (not shown); depositing an inner spacer material (not shown, for forming the inner spacers 52) to fill the recesses using any suitable deposition process; and removing an excess amount of the inner spacer material using any suitable etching process, thereby forming the inner spacer material into the inner spacers 52. In some embodiments, the inner spacers 52 include or are made of a dielectric material (e.g., silicon oxide, silicon oxycarbide, silicon nitride, silicon oxynitride, silicon carbide, silicon oxycarbonitride, an air gap, other suitable low-k dielectric materials, or combinations thereof), or other suitable materials. The dielectric features 24B at the second device region are shaded by the blocking layers 27, and thus remain intact.

Afterwards, at the first device region, the bottom isolation features 28 are respectively formed over the bottom epitaxial layers 26, so as to separate the source/drain features 53 from the bottom epitaxial layers 26 and the fins 12, thereby preventing current from leaking to the fins 12. At the second device region, the bottom isolation features 28 are respectively formed over and in contact with the blocking layers 27 so as to separate the source/drain features 53 from the dummy channels 21B, thereby preventing undesirable current leakage. In some embodiments, the bottom isolation features 28 may be formed by any suitable deposition process (e.g., APCVD, LPCVD, PECVD, ALD, or combinations thereof) followed by any suitable etching process (e.g., wet etching process, dry etching process, or combinations thereof). In some embodiments, the bottom isolation features 28 serve as insulators, and include or are made of a dielectric material (e.g., silicon oxide, silicon nitride, silicon oxynitride, silicon oxycarbonitride, silicon carbon-nitride, or combinations thereof), or other suitable materials. In some embodiments, at each of the first and second device regions, there may be only one bottom isolation feature 28 formed over one of two adjacent ones of the source/drain features 53. In some embodiments, the bottom isolation features 28 may also referred to as flexible bottom isolation (FBI) features.

After forming the source/drain features 53 at each of the first and second device regions, the contact etch stop layers (CESLs) 54 and interlayer dielectrics (ILDs) 55 (see FIG. 14) are formed. In some embodiments, the CESLs 54 and the ILDs 55 are formed by: sequentially depositing a CESL material (not shown, for forming the CESLs 54) and a ILD material (not shown, for forming the ILDs 55) over the source/drain features 53 using any suitable deposition process; and performing a planarization process (e.g., CMP), or other suitable process to remove an excess amount of each of the CESL and ILD dielectric materials, and to remove the masks 43 above the dummy structures 40 (see FIG. 13). After removal of the masks 43, at each of the first and second device regions, the dummy gate 42 of each of the remaining dummy structures (also denoted by 40) is exposed.

In some embodiment, each of the CESL material and the ILD material includes or is made of a dielectric material (e.g., silicon oxide, silicon nitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or combinations thereof), or other suitable materials. The CESL 54 and the ILD 55 are made of different materials.

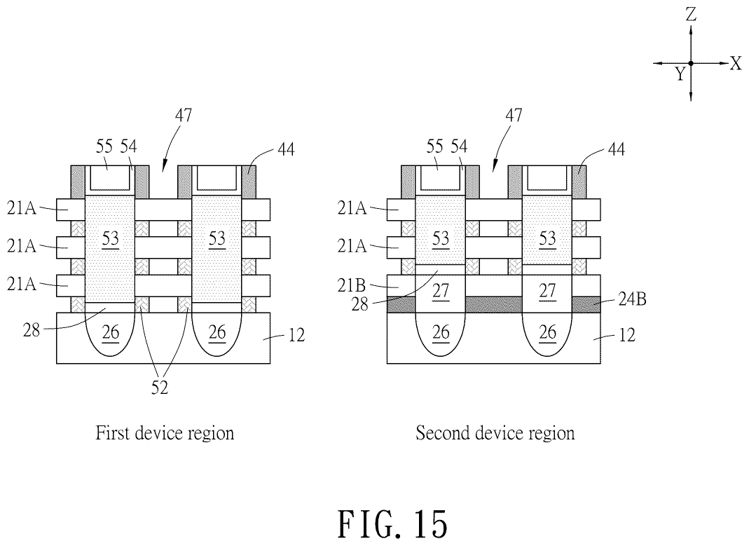

Referring to FIG. 15, at both the first and second device regions, the sacrificial interposers 25, and the dummy dielectrics 41 and the dummy gates 42 of the remaining dummy structures 40 (see FIG. 14) are removed to form cavities 47.

In some embodiments, the dummy dielectrics 41, the dummy gates 42 and the sacrificial interposers 25 may be removed using any suitable etching process (e.g., wet etching process, dry etching process, or combinations thereof) or other suitable processes, while the channels 21A, the dummy channels 21B, and the dielectric features 24B remain intact. In addition, the etchant(s) for removing the sacrificial interposers 25 have a higher etching selectively to the sacrificial interposers 25 than to the dielectric features 24B. In other words, during formation of the cavities 47, the sacrificial interposers 25 exhibit an etching rate that is at least about 50 times (e.g., about 50 times to about 100 times, about 80 times to about 100 times, or more than 100 times) higher than an etching rate of the dielectric features 24B that remains in the second device region.

Referring to FIG. 16, gate structures 60 are respectively formed in the cavities 47 (see FIG. 15) at the first and second device regions. Each of the gate structures 60 includes a gate dielectric layer 62 and a gate electrode 63. In some embodiments, prior to forming the gate structures 60, interfacial layers (ILs) 61 are formed around the channels 21A, surface portions of the dummy channels 21B (exposed to the cavities 47) and surface portions of the fins 12 (exposed to the cavities 47, not shown). In each of the cavities 47, the gate dielectric layer 62 is formed over the structure obtained after forming the ILs 61. Thereafter, the gate electrode 63 is formed over the gate dielectric layer 62 to fill each of the cavities 47. In some embodiments, at the second device region, each of the dummy channels 21B (serving as a lower one of the first semiconductor features 21′, see also FIG. 12) has an upper surface and a lower surface. The upper surface of each dummy channel 21B is connected to a corresponding one of the gate structures 60, and a lower surface of each dummy channel 21B is connected to a corresponding one of the dielectric features 24B (serving as the lower one of the dielectric features 24, see also FIG. 12). In addition, each of the dielectric features 24B has an upper surface connected to the lower surface of a corresponding one of the dummy channels 21B, and two side surfaces opposite to each other in the Y direction. The two side surfaces of each dielectric feature 24B are covered by a corresponding one of the gate structures 60.

In some embodiments, the ILs 61 are made of silicon oxide, and are formed through an oxidation reaction that occurs on an exposed surface of silicon (i.e., the exposed surface portion of each of the channels 21A, the dummy channels 21B and the fins 12). Other suitable materials and/or processes for forming the ILs 61 are within the contemplated scope of the present disclosure.

In some embodiments, the gate dielectric layer 62 and the gate electrode 63 are formed as follows. A gate dielectric material is conformally formed over the structure obtained after forming the ILs 61 by using any suitable deposition process (e.g., CVD, thermal ALD, plasma ALD, or combinations thereof), or other suitable processes. Then, a gate electrode material (not shown) is formed over the gate dielectric material to fill the cavities 47 by using any suitable deposition process (e.g., PVD process, CVD process, ALD process, or combinations thereof), or other suitable processes. Afterwards, excess amounts of the gate dielectric material and the gate electrode material are removed by a planarization process (e.g., CMP) to expose the CESLs 54 and ILDs 55. After the planarization process, the gate dielectric material and the gate electrode material are formed into the gate dielectric layer 62 and the gate electrode 63, respectively. Step 106 in the flow diagram shown in FIG. 1 is exemplified by structures shown in FIGS. 15 to 16.

In some embodiments, the gate dielectric layer 62 includes or is made of silicon oxide, silicon nitride, silicon oxynitride, a high dielectric constant material, or other suitable materials. The gate dielectric layer 62 has a dielectric constant (k value) that is higher than a dielectric constant of each of the gate spacers 44, the CESLs 54, and ILDs 55. The high dielectric constant material may be a dielectric material with wide band gap and good thermal stability. Examples of the high dielectric constant material are a hafnium-based dielectric material (e.g. hafnium oxide), zirconium oxide, titanium oxide, yttrium oxide, magnesium oxide, calcium oxide, zirconium silicate, aluminum oxide, scandium oxide, or other suitable materials.

In some embodiments, the gate electrode 63 includes or is made of a metal material (e.g., tungsten (W), titanium (Ti), tantalum (Ta), aluminum (Al), or ruthenium (Ru)), metal-containing nitrides (e.g., titanium nitride (TiN), or tantalum nitride (TaN)), metal-containing silicides (e.g., nickel silicide (NiSi)), metal-containing carbides (e.g., tantalum carbide (TaC)), or combinations thereof, other suitable materials. In some embodiments, the gate electrode may include or may be made of various n-type or p-type work function metals. Examples of the n-type work function metal include Al, titanium aluminum carbide (TiAlC), TiAl, or other suitable materials. Examples of p-type work function metals include TiN, tungsten nitride (WN), tungsten carbon nitride (WCN), molybdenum nitride (MoN), or other suitable materials. In some embodiments, the gate electrode 63 includes a titanium-based material.

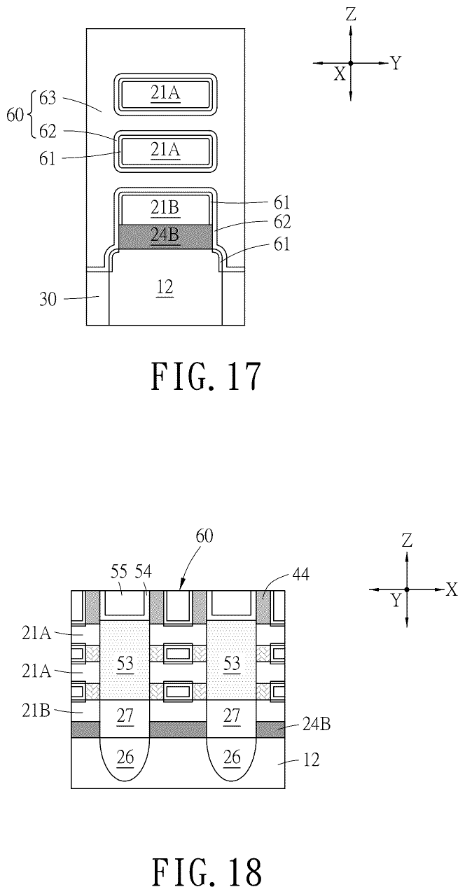

FIG. 17 is a schematic cross-sectional view (Z-cut) taken along the line B-B shown in FIG. 14 in accordance with some embodiments. In some embodiments, a width of each of the dielectric features 24B measured along the Y direction is smaller than a width of an upper surface of a corresponding one of the fins 12 measured along the Y direction.

After forming the gate structures 60, the semiconductor structure (which may be also referred to as a hybrid channel structure) is obtained. At the first device region, GAA devices formed thereon each includes three of the channels 21A (and are known as 3-channel devices). At the second device region, GAA devices formed thereon each includes two of the channels 21A (and are known as 2-channel devices) and one of the dummy channels 21B. Specifically, for the 2-channel devices, the dielectric features 24B (instead of the gate structures 60) are formed beneath the dummy channels 21B. Thus, compared with the 2-channel devices in other hybrid channel structures, the 2-channel devices of the present disclosure exhibit a significantly low parasitic capacitance, thereby improving net performance and power efficiency of the semiconductor structure. In contrast, in the 2-channel devices of the other hybrid channel structures, a portion of the gate structure is located beneath the dummy channels, and is unused. Such unused portion of the gate structure undesirably exhibits a relatively high parasitic capacitance. It is noted that the semiconductor structure of the present disclosure may save about 3% to about 5% power consumption in comparison with the other hybrid channel structure. Although the above steps are exemplified for forming GAA devices, those steps may be modified for forming a forksheet transistor, a complementary field-effect transistor (CFET) or other suitable devices.

In the present disclosure, in order to obtain the 2-channel devices, the method includes performing the first replacement process (i.e., step 102), forming the blocking layers 27 (i.e., step 103), and performing the second replacement process (i.e., step 104). The first replacement process is first performed to form the dielectric features 24A, 24B, particularly the dielectric features 24B at predetermined locations, e.g., between the dummy channels 21B and the corresponding fin 12, so as to prevent formation of the gate structures 60 at such predetermined locations. The second replacement process is performed to replace the dielectric features 24A with the sacrificial interposers 25. It is noted that the sacrificial interposers 25 and the dielectric features 24B are made of different materials, such that the removal process of step 106 is performed in a selective manner, where the sacrificial interposers 25 are removed, and the dielectric features 24B remain. In order to replace only the dielectric features 24A, and for the dielectric features 24B to remain in the second replacement process, the blocking layers 27 are configured to shield the dielectric features 24B and expose the dielectric features 24A.

In some embodiments, where the 3-channel devices are not required, the first device region may be omitted and merely the second device region having the 2-channel devices is formed. In such case, the blocking layers 27 and the bottom epitaxial layers 26 may be formed in a single deposition process using the same material (i.e., no distinct interface present between each of the blocking layers 27 and a corresponding one of the bottom epitaxial layers 26), or may be formed in different deposition processes using different materials.

The semiconductor structure shown in FIG. 16 may be subjected to further processes to suit different purposes, e.g., application in a front side power delivery network (FSPDN), or a back side power delivery network (BSPDN). Other suitable application for the semiconductor structure are within the contemplated scope of the present disclosure. FIG. 18 describes a variation of the semiconductor structure in comparison with the structure shown in FIG. 16. FIGS. 19 to 27 describe further possible processes subsequent to the structure shown in FIG. 18 for application in BSPDN, in accordance with some embodiments. It should be noted that the structures in FIGS. 19 to 27 are turned upside down (in the vertical direction (Z)) in comparison with the structure shown in FIG. 18 for easy illustration.

FIG. 18 is a cross-sectional view of a second device region in accordance with some embodiments. The second device region shown in FIG. 18 is similar to that shown in FIG. 16 except that the bottom isolation features 28 are omitted, and that the bottom epitaxial layers 26 and the blocking layers 27 are each made of a material different from a material of the channels 21A and the dummy channels 21B and a material of the fins 12.

Referring to FIG. 19, the base 11 and the fin 12 (see FIGS. 6 and 18) in the structure shown in FIG. 18 are removed to expose the dielectric features 24B and the bottom epitaxial layers 26 in accordance with some embodiments. In some embodiments, an upper surface (which is distal from a respective one of the source/drain features 53) of each of the blocking layers 27 and an upper surface of each of the dielectric features 24B are substantially coplanar.

In some embodiments, the base 11 and the fin 12 are removed by: performing a wafer thinning process by any suitable process (e.g., a polishing process (e.g., CMP), an etching process, or combinations thereof), or other suitable processes to thin down the substrate 10 (see also FIG. 3) from a backside of the substrate 10; and removing the base 11 and the fin 12 by any suitable etching process (e.g., dry etching process, wet etching process, or combinations thereof) or other suitable processes, so as to expose the bottom epitaxial layers 26 and the dielectric features 24B while the bottom epitaxial layers 26 and the blocking layers 27 remain intact. In some embodiments, the isolation features 30 (see FIG. 6) may be also partially or fully removed.

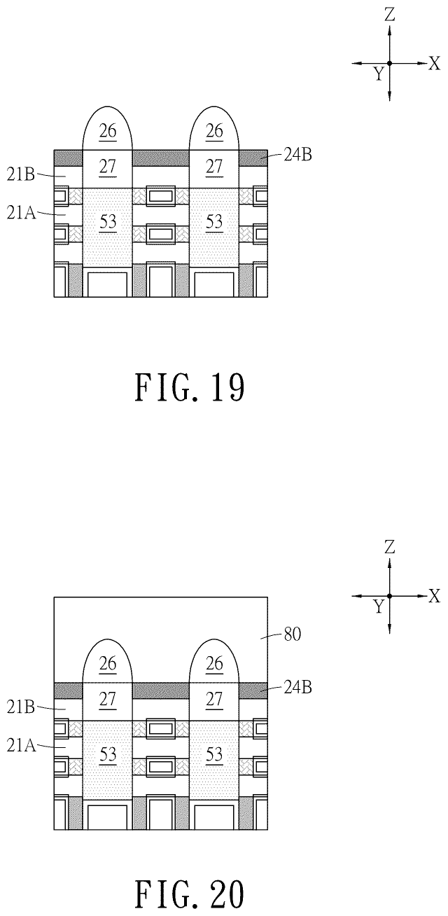

Referring to FIG. 20, a first dielectric layer 80 is formed over the dielectric features 24B and the bottom epitaxial layers 26.

In some embodiments, the first dielectric layer 80 is formed by: depositing a dielectric material (for forming the first dielectric layer 80) by any suitable deposition process (e.g., APCVD, LPCVD, PECVD, ALD, or combinations thereof), or other suitable processes; and performing a planarization process (e.g., CMP), or other suitable process to remove an excess amount of the first dielectric layer 80.

In some embodiments, the first dielectric layer 80 includes or is made of silicon oxide, silicon nitride, silicon carbide, silicon carbonitride, silicon oxynitride, silicon oxycarbide, silicon oxycarbonitride, or combinations thereof, or other suitable materials.

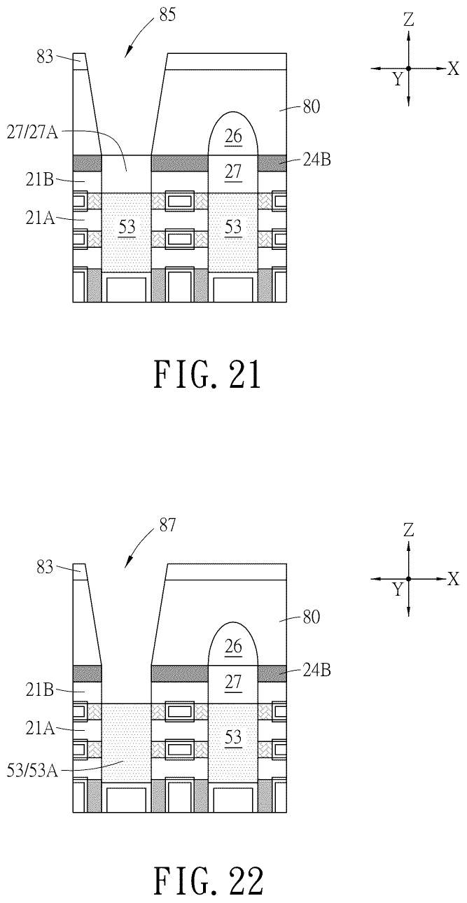

Referring to FIG. 21, a second dielectric layer 83 is formed over the first dielectric layer 80. In addition, a first opening 85 is formed in the first dielectric layer 80 and the second dielectric layer 83, so as to expose one of the blocking layers 27, which is also denoted as 27A. In some embodiments, the blocking layer 27A is free from coverage by the first dielectric layer 80 and the second dielectric layer 83.

In some embodiments, the second dielectric layer 83 is formed by any suitable deposition process (e.g., APCVD, LPCVD, PECVD, ALD, or combinations thereof), or other suitable processes. Thereafter, the first opening 85 is formed by: performing a photolithography process or other suitable process to form a patterned photoresist layer (not shown) over the second dielectric layer 83; and performing any suitable etching process (e.g., dry etching process, wet etching process, or combinations thereof) or other suitable process to form the first opening 85 so as to expose the blocking layer 27A. In some embodiments, the first opening 85 has a tapered profile, or a straight profile, or other suitable profiles.

Possible materials for the second dielectric layer 83 are similar to those for the first dielectric layer 80, and the details thereof are omitted for the sake of brevity. In some embodiments, the second dielectric layer 83 and the first dielectric layer 80 are different in terms of the materials they are made of. In some embodiments, the first dielectric layer 80 is made of a nitride-based dielectric material (e.g. silicon nitride), and the second dielectric layer 83 is made of an oxide-based dielectric material (e.g., silicon oxide).

Referring to FIG. 22, the blocking layer 27A (see FIG. 21) is removed to form a second opening 87 such that a corresponding one of the source/drain features 53, which is also denoted as 53A, is exposed.

In some embodiments, the blocking layer 27A is removed by any suitable process, e.g., a wet etching process, a dry etching process, or combinations thereof. It is noted that a material of the blocking layer 27A is different from the materials of adjacent elements (e.g., materials of corresponding dummy channels 21B and the source/drain feature 53A). As such, in the removal process, an etching rate of the blocking layer 27A is much higher than an etching rate of the corresponding dummy channels 21B and an etching rate of the source/drain features 53A. Thus the blocking layer 27A is removed while the corresponding dummy channels 21B and the source/drain feature 53A remain substantially intact. In addition, the corresponding dielectric features 24 also remain intact.

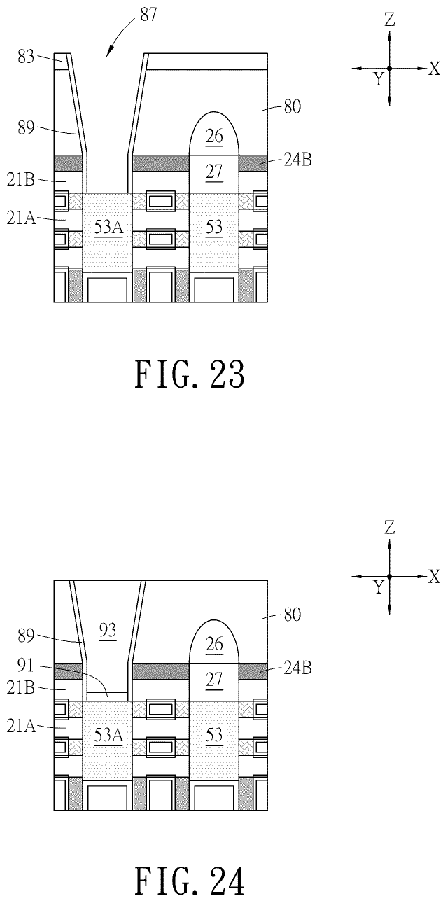

Referring to FIG. 23, a first liner 89 is formed in the second opening 87 over sidewalls of the corresponding dummy channels 21B, the corresponding dielectric features 24B, the first dielectric layer 80, and the second dielectric layer 83. The source/drain feature 53A is exposed from the first liner 89.

In some embodiments, the first liner 89 is formed by: conformally depositing a dielectric material (for forming the first liners 89) over the structure shown in FIG. 22 by any suitable deposition process (e.g., CVD, ALD, or combinations thereof) or other suitable processes; removing an excess amount of the dielectric material by any suitable etching process (e.g., an anisotropic etching process) or other suitable process from the upper surface of the source/drain feature 53A and from an upper surface of the second dielectric layer 83. In some embodiments, after the first liner 89 is formed, an ion implantation process is performed to introduce an n-type impurity or a p-type impurity on the source/drain feature 53A. Examples of the n-type impurity and the p-type impurity are similar to those described with reference to FIG. 2, and thus the details thereof are omitted for the sake of brevity. In some embodiments, prior to the ion implantation process, a mask layer (not shown) may be formed to cover the elements other than the source/drain feature 53A using a deposition process followed by a patterning process so as to prevent the other elements from being undesirably doped. After the ion implantation process, the mask layer is removed.

In some embodiments, the first liner 89 includes or is made of silicon oxide, silicon nitride, silicon carbide, silicon carbonitride, silicon oxynitride, silicon oxycarbide, silicon oxycarbonitride, aluminum oxide, aluminum oxynitride, hafnium oxide, titanium oxide, zirconium oxide, zirconium aluminate, zinc oxide, or combinations thereof, or other suitable materials.

Referring to FIG. 24, a silicide portion 91 is formed on the source/drain feature 53A. In some embodiments, an upper surface of the silicide portion 91 is lower than surfaces (connected to the dielectric features 24B) of the corresponding dummy channels 21B.

In some embodiments, the silicide portion 91 is formed by: depositing a metal-containing layer (not shown) over the structure shown in FIG. 23 by any suitable deposition process (e.g., CVD, PVD, or combinations thereof) or other suitable process; performing a treatment process to allow a portion of the metal-containing layer that is deposited on the source/drain feature 53A to react with silicon in the source/drain feature 53A; and removing a non-reacted portion of the metal-containing layer (not shown) by any suitable etching process (e.g., wet etching process, dry etching process, or combinations thereof) or other suitable process, so as to form the silicide portion 91.

In some embodiments, the silicide portion 91 includes or is made of titanium silicide, ruthenium silicide, nickel silicide, cobalt silicide, molybdenum silicide, or combinations thereof, or other suitable materials.

After forming the silicide portion 91, a backside via 93 is formed on the silicide portion 91 and filling the second opening 87 (see FIG. 23), such that the backside via 93 is connected to the source/drain feature 53A through the silicide portion 91. In addition, the second dielectric layer 83 (see also FIG. 23) is removed. A back surface of the backside via 93 and a back surface of the first dielectric layer 80 are substantially coplanar. In some embodiments, the backside via 93 may be connected to other elements, e.g., a power delivery feature (not shown), such that the device is connected to the power delivery feature through the backside via. Other suitable connections are within the contemplated scope of the present disclosure.

In some embodiments, the backside via 93 is formed by: depositing a conductive material (not shown, for forming the backside via 93) over the silicide portion 91 to fill the second opening 87 (see FIG. 23) by any suitable deposition process (e.g., CVD, PVD, or combinations thereof) or other suitable processes; and performing a planarization process (e.g., CMP) to remove the second dielectric layer 83 (see FIG. 23), and an excess amount of the conductive material.

In some embodiments, the backside via 93 includes or is made of tungsten (W), aluminum (Al), ruthenium (Ru), cobalt (Co), copper (Cu), palladium (Pd), nickel (Ni), platinum (Pt), a low resistivity metal constituent, combinations thereof, or other suitable materials.

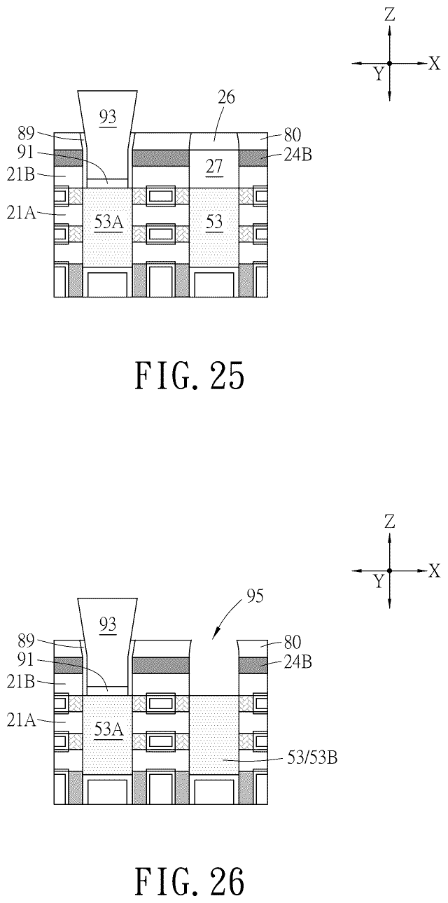

Referring to FIG. 25, the first dielectric layer 80, the first liner 89, and the remaining bottom epitaxial layer 26 shown in FIG. 24 are etched back, while the backside via 93 remains intact. The backside via 93 protrudes from the back surface of the remaining first dielectric layer 80. In other words, the back surface of the backside vias 93 is located at a level higher than a level of the back surface of the remaining first dielectric layer 80. The back surface of the remaining first dielectric layer 80 and the back surfaces of the remaining bottom epitaxial layer 26 are substantially coplanar.

In some embodiments, the first dielectric layer 80, the first liner 89, the remaining bottom epitaxial layer 26 shown in FIG. 24 are etched back by any suitable etching process (e.g., wet etching process, dry etching process, or combinations thereof) or other suitable processes. In some embodiments, prior to the etch-back process, a photolithography process, or other suitable process, is performed to form a patterned photoresist layer (not shown) over the backside via 93 to protect the backside via 93 in the etch-back process.

Referring to FIG. 26, the remaining bottom epitaxial layer 26 and the remaining blocking layer 27 are removed to form a third opening 95 exposing a corresponding one of source/drain features which is also denoted by 53B.

In some embodiments, the remaining bottom epitaxial layer 26 and the remaining blocking layer 27 are removed by any suitable etching process (e.g., wet etching process, dry etching process, or combinations thereof) or other suitable processes. In some embodiments, the backside via 93, the remaining first liner 89 and the remaining first dielectric layer 80 remain intact after the removal process.

Referring to FIG. 27, a second liner 97 and a third dielectric layer 99 are formed over the structure shown in FIG. 26. FIG. 28 is a schematic cross-sectional view (Z-cut) taken along the line C-C shown in FIG. 27 in accordance with some embodiments. In some embodiments, the second liner 97 is conformally formed over a back side profile shown in FIG. 26 (i.e., over the back side profile provided by the first dielectric layer 80, the corresponding dielectric features 24B, the corresponding dummy channels 21B, the source/drain feature 53B and the backside via 93). In some embodiments, the second liner 97 may also be referred to as a backside flexible bottom isolation (BS-FBI) feature. In addition, the third dielectric layer 99 is formed over the second liners 97 to fill the third opening 95 (see FIG. 26). In some embodiments, a back surface of the third dielectric layer 99 and the back surface of the backside via 93 are substantially coplanar.

In some embodiments, the second liner 97 and the third dielectric layer 99 are formed by: depositing a first dielectric material (not shown, for forming the second liner 97) by any suitable deposition process (e.g., APCVD, LPCVD, PECVD, ALD, or combinations thereof), or other suitable processes over the structure shown in FIG. 26; depositing a second dielectric material (not shown, for forming the third dielectric layer 99) by any suitable deposition process (e.g., APCVD, LPCVD, PECVD, ALD, or combinations thereof) or other suitable processes to fill the third opening 95; performing a planarization process (e.g., CMP) or other suitable processes to remove excess amounts of each of the first dielectric material and the second dielectric material, thereby obtaining the second liner 97 and the third dielectric layer 99, and to expose the backside via 93.

Possible materials for the second liner 97 are similar to those for the first liner 89, and thus details thereof are omitted for the sake of brevity. In some embodiments, the second liner 97 and the first liners 89 are made of the same material. In other embodiments, the second liner 97 and the first liner 89 are made of different materials.

Possible materials for the third dielectric layer 99 are similar to those for the first dielectric layer 80, and thus details thereof are omitted for the sake of brevity. In some embodiments, the first dielectric layer 80 and the third dielectric are made of different materials.

The embodiments of the method for manufacturing the semiconductor structure in the present disclosure have the following advantageous features. By using the method of this disclosure, at the second device region, instead of the gate structures 60, each of the dielectric features 24B is formed between one of the dummy channels 21B and the corresponding fin 12 (if any). As such, compared with devices with a gate structure penetrating into a space between a dummy channel and a fin structure, the devices with the dummy channels 21B and the dielectric features 24B of this disclosure exhibit a significantly lower parasitic capacitance, thereby improving net performance and power efficiency of the semiconductor structure. In addition, the method of this disclosure is also compatible with other processes (e.g., FSPDN and BSPDN) applied to the structure made by this method.

In accordance with some embodiments of the present disclosure, a method for manufacturing a semiconductor structure includes: forming a patterned structure which includes: an active region disposed between two isolation features; a stack portion disposed on the active region, and including first semiconductor features and second semiconductor features that are alternately stacked, a material of the first semiconductor features being different from a material of the second semiconductor features; a dummy structure formed over the stack portion and the two isolation features; performing a first replacement process to replace the second semiconductor features with dielectric features, respectively; forming two blocking layers, two ends of a lower one of the dielectric features and two ends of a lower one of the first semiconductor features being covered by the two blocking layers, and two ends of an upper one of the dielectric features and two ends of an upper one of the first semiconductor features being exposed from the two blocking layers; after forming the two blocking layers, performing a second replacement process to replace the upper one of the dielectric features with a sacrificial interposer, a material of the sacrificial interposer being different from a material of the dielectric features; after the second replacement process, forming two source/drain features respectively on the two blocking layers; removing the sacrificial interposer and the dummy structure to form a cavity; forming a gate structure in the cavity, the gate structure including a Ti-based gate electrode and a gate dielectric.

In accordance with some embodiments of the present disclosure, the two blocking layers are formed using an epitaxy growing process.

In accordance with some embodiments of the present disclosure, the two source/drain features are made of an epitaxial material having a dopant concentration higher than a dopant concentration of the two blocking layers.

In accordance with some embodiments of the present disclosure, the two blocking layers are made of a material different from a material of the channel features.

In accordance with some embodiments of the present disclosure, in removing the sacrificial interposer, the sacrificial interposer has an etching rate higher than an etching rate of the lower one of the dielectric features.

In accordance with some embodiments of the present disclosure, the dielectric features include silicon oxide, aluminum oxide, hafnium oxide, titanium oxide, zirconium oxide, silicon nitride, silicon carbide, silicon oxynitride, silicon oxycarbide, silicon oxycarbonitride, or combinations thereof.

In accordance with some embodiments of the present disclosure, the sacrificial interposer includes aluminum oxide, hafnium oxide, titanium oxide, zirconium oxide, silicon nitride, silicon carbide, silicon oxynitride, silicon oxycarbide, silicon oxycarbonitride, or combinations thereof.

In accordance with some embodiments of the present disclosure, after forming the gate structure, the lower one of the first semiconductor features has an upper surface being connected to the gate structure, and a lower surface being connected to the lower one of the dielectric features.

In accordance with some embodiments of the present disclosure, the method further includes forming two bottom epitaxial layers beneath the two blocking layers.

In accordance with some embodiments of the present disclosure, a method for manufacturing a semiconductor structure includes: forming a patterned structure which includes: an active region disposed between two isolation features, each of the active region and the two isolation features extending along a first direction; a stack portion disposed on the active region, and including dielectric features and semiconductor features that are alternately stacked; and a dummy structure formed over the stack portion and the two isolation features, the dummy structure extending along a second direction different from the first direction; forming two blocking layers, upper surfaces of the two blocking layers being not lower than an upper surface of a lower one of the dielectric features; after forming the two blocking layers, performing a replacement process to replace an upper one of the dielectric features with a sacrificial interposer, a material of the sacrificial interposer being different from a material of the dielectric features; after the replacement process, forming two source/drain features respectively on the two blocking layers; and removing the sacrificial interposer and the dummy structure to form a cavity; forming a gate structure in the cavity.

In accordance with some embodiments of the present disclosure, each of the semiconductor features has an upper surface and a lower surface that are opposite to each other in a third direction different from the first direction and the second direction; and after forming the cavity, the upper surface of a lower one of the semiconductor features is exposed to the cavity, and the lower surface of the lower one of the semiconductor features is covered by the lower one of the dielectric features.

In accordance with some embodiments of the present disclosure, the method further includes forming two bottom isolation feature respectively on the two blocking layers before forming the two source/drain features.

In accordance with some embodiments of the present disclosure, the method further includes, after forming the gate structure: removing the active region to expose the lower one of the dielectric features; forming a first dielectric layer on the dielectric features opposite to the gate structure; forming a first opening to expose one of the two blocking layers; removing the one of the two blocking layers to expose a corresponding one of the two source/drain features; and forming a conductive feature on the corresponding one of the two source/drain features.

In accordance with some embodiments of the present disclosure, the method further includes, after forming the conductive feature: removing a portion of the first dielectric layer and the other one of the two blocking layers, the other one of the two source/drain features being exposed from a second opening, and the conductive feature being protruded from the first dielectric layer; forming a liner over the first dielectric layer, over the conductive feature, and over the other one of the two source/drain features; and forming another dielectric layer over the liner.

In accordance with some embodiments of the present disclosure, a material of one of the two blocking layers is different from a material of the semiconductor features and a material of the corresponding one of the two source/drain features.

In accordance with some embodiments of the present disclosure, in removing the one of the two blocking layers, a lower one of the semiconductor features is exposed, an etching rate of the two blocking layers being higher than an etching rate of the lower one of the semiconductor features and an etching rate of the corresponding one of the two source/drain features.

In accordance with some embodiments of the present disclosure, the method further includes forming two bottom epitaxial layers prior to forming the two blocking layers.

In accordance with some embodiments of the present disclosure, the two blocking layers are formed using an epitaxy growing process.

In accordance with some embodiments of the present disclosure, a semiconductor structure includes: an active channel feature and a dummy channel feature disposed beneath the active channel feature; two source/drain features; a gate structure; and a dielectric feature. The two source/drain features are disposed at two opposite sides of a combination of the active channel feature and the dummy channel feature in a first direction, and are interconnected by the active channel feature. The gate structure is formed to surround the active channel feature and formed over the dummy channel feature. The gate structure extends lengthwise along a second direction different from the first direction. The gate structure includes a Ti-based gate electrode and a gate dielectric. The dielectric feature has an upper surface connected to a lower surface of the dummy channel feature opposite to the active channel feature.

In accordance with some embodiments of the present disclosure, the dielectric feature further has two side surfaces opposite to each other in the second direction, the two side surfaces being covered by the gate structure.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a patterned structure which includes:
an active region disposed between two isolation features;
a stack portion disposed on the active region, and including first semiconductor features and second semiconductor features that are alternately stacked, a material of the first semiconductor features being different from a material of the second semiconductor features;
a dummy structure formed over the stack portion and the two isolation features;
performing a first replacement process to replace the second semiconductor features with dielectric features, respectively;
forming two blocking layers,
two ends of a lower one of the dielectric features and two ends of a lower one of the first semiconductor features being covered by the two blocking layers, and
two ends of an upper one of the dielectric features and two ends of an upper one of the first semiconductor features being exposed from the two blocking layers;
after forming the two blocking layers, performing a second replacement process to replace the upper one of the dielectric features with a sacrificial interposer, a material of the sacrificial interposer being different from a material of the dielectric features;
after the second replacement process, forming two source/drain features respectively on the two blocking layers;
removing the sacrificial interposer and the dummy structure to form a cavity;
forming a gate structure in the cavity, the gate structure including a Ti-based gate electrode and a gate dielectric.

2. The method of claim 1, wherein the two blocking layers are formed using an epitaxy growing process.

3. The method of claim 1, wherein the two source/drain features are made of an epitaxial material having a dopant concentration higher than a dopant concentration of the two blocking layers.

4. The method of claim 1, wherein the two blocking layers are made of a material different from a material of the channel features.

5. The method of claim 1, wherein in removing the sacrificial interposer, the sacrificial interposer has an etching rate higher than an etching rate of the lower one of the dielectric features.

6. The method of claim 1, wherein the dielectric features include silicon oxide, aluminum oxide, hafnium oxide, titanium oxide, zirconium oxide, silicon nitride, silicon carbide, silicon oxynitride, silicon oxycarbide, silicon oxycarbonitride, or combinations thereof.

7. The method of claim 1, wherein the sacrificial interposer includes aluminum oxide, hafnium oxide, titanium oxide, zirconium oxide, silicon nitride, silicon carbide, silicon oxynitride, silicon oxycarbide, silicon oxycarbonitride, or combinations thereof.

8. The method of claim 1, wherein after forming the gate structure, the lower one of the first semiconductor features has an upper surface being connected to the gate structure, and a lower surface being connected to the lower one of the dielectric features.

9. The method of claim 1, further comprising forming two bottom epitaxial layers beneath the two blocking layers.

10. A method for manufacturing a semiconductor structure, comprising:
forming a patterned structure which includes:
an active region disposed between two isolation features, each of the active region and the two isolation features extending along a first direction;
a stack portion disposed on the active region, and including dielectric features and semiconductor features that are alternately stacked; and
a dummy structure formed over the stack portion and the two isolation features, the dummy structure extending along a second direction different from the first direction;
forming two blocking layers, upper surfaces of the two blocking layers being not lower than an upper surface of a lower one of the dielectric features;
after forming the two blocking layers, performing a replacement process to replace an upper one of the dielectric features with a sacrificial interposer, a material of the sacrificial interposer being different from a material of the dielectric features;
after the replacement process, forming two source/drain features respectively on the two blocking layers;
removing the sacrificial interposer and the dummy structure to form a cavity; and
forming a gate structure in the cavity.

11. The method of claim 10, wherein:
each of the semiconductor features has an upper surface and a lower surface that are opposite to each other in a third direction different from the first direction and the second direction; and
after forming the cavity, the upper surface of a lower one of the semiconductor features is exposed to the cavity, and the lower surface of the lower one of the semiconductor features is covered by the lower one of the dielectric features.

12. The method of claim 10, further comprising forming two bottom isolation feature respectively on the two blocking layers before forming the two source/drain features.

13. The method of claim 10, further comprising, after forming the gate structure:
removing the active region to expose the lower one of the dielectric features;
forming a first dielectric layer on the dielectric features opposite to the gate structure;
forming a first opening to expose one of the two blocking layers;
removing the one of the two blocking layers to expose a corresponding one of the two source/drain features; and
forming a conductive feature on the corresponding one of the two source/drain features.

14. The method of claim 13, further comprising, after forming the conductive feature:
removing a portion of the first dielectric layer and the other one of the two blocking layers, the other one of the two source/drain features being exposed from a second opening, and the conductive feature being protruded from the first dielectric layer;
forming a liner over the first dielectric layer, over the conductive feature, and over the other one of the two source/drain features; and
forming another dielectric layer over the liner.

15. The method of claim 13, wherein a material of one of the two blocking layers is different from a material of the semiconductor features and a material of the corresponding one of the two source/drain features.

16. The method of claim 13, wherein in removing the one of the two blocking layers, a lower one of the semiconductor features is exposed, an etching rate of the two blocking layers being higher than an etching rate of the lower one of the semiconductor features and an etching rate of the corresponding one of the two source/drain features.

17. The method of claim 10, further comprising forming two bottom epitaxial layers prior to forming the two blocking layers.

18. The method of claim 10, wherein the two blocking layers are formed using an epitaxy growing process.

19. A semiconductor structure, comprising:
an active channel feature and a dummy channel feature disposed beneath the active channel feature;
two source/drain features disposed at two opposite sides of a combination of the active channel feature and the dummy channel feature in a first direction, the two source/drain features being interconnected by the active channel feature;
a gate structure formed to surround the active channel feature and formed over the dummy channel feature, the gate structure extending lengthwise along a second direction different from the first direction, the gate structure including a Ti-based gate electrode and a gate dielectric; and
a dielectric feature having an upper surface connected to a lower surface of the dummy channel feature opposite to the active channel feature.

20. The semiconductor structure of claim 19, wherein the dielectric feature further has two side surfaces opposite to each other in the second direction, the two side surfaces being covered by the gate structure.
